(19) United States
(12) Patent Application Publication
(10) Pub. No.: US 2026/0018420 A1
(43) Pub. Date: Jan. 15, 2026

(54) SUBSTRATE PROCESSING METHOD

(71) Applicant: PSK INC., Hwaseong-si, Gyeonggi-do (KR)

(72) Inventors: Yun Young LEE, Hwaseong-si, Gyeonggi-do (KR); Jin Chul SON, Hwaseong-si, Gyeonggi-do (KR)

(21) Appl. No.: 19/114,114

(22) PCT Filed: Sep. 14, 2023
(86) PCT No.: PCT/KR2023/013796

§ 371 Date: Mar. 21, 2025

(30) Foreign Application Priority Data
Sep. 21, 2022 (KR) 10-2022-0119576

(51) Int. Cl. H01L 21/311; H01L 21/033

(52) U.S. Cl. CPC H01L 21/31122; H01L 21/0332

(57) ABSTRACT

The present invention provides a substrate processing method. A substrate processing method according to an embodiment may include a first step of supplying a process gas to a chamber and exciting the process gas to react with a specific film formed on the substrate to generate a reaction product, and a second step of supplying a dissociation gas to the chamber and exciting the dissociation gas to remove the reaction product from the substrate.

### TECHNICAL FIELD

The present invention relates to a substrate processing method, and more particularly to a substrate processing method for removing a hard mask film formed on a substrate.

### BACKGROUND ART

In general, semiconductor devices may be fabricated by a unit process of a photolithography process, an etching process, a deposition process, and/or an ion implantation process. A photolithography process is a process that forms a photoresist film on a substrate. The photoresist film may function as a mask pattern that selectively exposes the substrate. Additionally, a hard mask film may be formed on the underside of the photoresist film. The hard mask film can perform functions such as preventing collapse of the circuit pattern formed on the substrate. The photoresist film and the hard mask film may be sequentially removed from the substrate in a strip-like manner after the ion implantation process or etching process is performed.

With the increase in etch targets and recent trends requiring fine patterns with high selectivity, the resistance of hard mask films to etching is being increased. For example, various impurities (e.g., carbon) can be added to the hard mask film to improve the line roughness of the profile of the hard mask film and simultaneously improve its resistance to etching. However, when impurities are added to the hard mask film in this manner, it is difficult to easily remove the hard mask film from the substrate after the etching process is completed. Specifically, the impurities added to the hard mask film may be oxidized during the process of removing the hard mask film. The oxidized impurities have a very high boiling point and are very difficult to remove even in subsequent treatment.

In addition, if higher temperatures and stronger density plasma are generated to remove the impurity-added hard mask film from the substrate, it is likely that not only the hard mask film but also the insulating film formed on the substrate will be damaged. If the insulating film formed on the substrate with a high selectivity ratio is damaged, it will result in a lower yield of the substrate. In addition, even if strong plasma is applied to the substrate, the impurity-added hard mask film is difficult to remove from the substrate. If the hard mask film remains on the substrate, subsequent processes will be less efficient in treating the substrate.

### Technical Problem

An object of the present invention is to provide a substrate processing method capable of efficiently processing a substrate.

Another object of the present invention is to provide a substrate processing method capable of efficiently removing a hard mask film formed on a substrate.

Another object of the present invention is to provide a substrate processing method capable of efficiently removing a hard mask film to which a specific substance has been added, while minimizing damage to an insulating film formed on the substrate.

The problem to be solved by the present invention is not limited to the above-mentioned problems, and the problems not mentioned will be clearly understood by those skilled in the art from the present specification and the accompanying drawings.

### TECHNICAL SOLUTION

An exemplary embodiment of the present invention provides a method of processing a substrate, the method comprising: a first operation of supplying process gas to a chamber, wherein the process gas may be excited to react with a specific film formed on a substrate to produce a reactant; and a second operation of supplying dissociation gas to the chamber, wherein the dissociation gas may be excited to remove the reactant from the substrate.

According to the exemplary embodiment, the process gas may include first gas reacting with the specific film formed on the substrate, and second gas that reacts with a surface of the film formed on the substrate to form a protective film on the surface or to etch the specific film.

According to the exemplary embodiment, the dissociation gas further may remove the protective film from the substrate.

According to the exemplary embodiment, the first operation and the second operation may be performed sequentially in one cycle, and repeated multiple times.

According to the exemplary embodiment, the first gas may include CF₄, SF₆, Cl₂, or HBr, the second gas includes O₂, and the dissociation gas includes inert gas.

According to the exemplary embodiment, the reactant may be volatilized at a set temperature in a range of 100 degrees Celsius to 150 degrees Celsius.

According to the exemplary embodiment, in the first operation, a chuck supporting the substrate within the chamber may be maintained at the set temperature, and in the second operation, bias power may be applied to the chuck.

According to the exemplary embodiment, the second operation may be performed before the first operation.

According to the exemplary embodiment, the specific film may be a hard mask film.

According to the exemplary embodiment, the hard mask film may include an additive including tungsten and a carbon layer.

According to the exemplary embodiment, a method of processing a substrate to remove a hard mask film formed on a substrate, the method comprising: supplying first gas to a chamber, wherein the first gas may be excited to react with a hard mask film formed on a substrate to produce a reactant, and supplying second gas different from the first gas to the chamber, wherein the second gas is excited to etch the hard mask film or react with an insulating film formed on the substrate to produce a protective film on the surface of the insulating film, and the first gas and the second gas are simultaneously supplied to the chamber.

According to the exemplary embodiment, the reactant may be volatilized at a set temperature in a range of 100 degrees Celsius to 150 degrees Celsius and may remove from the substrate.

According to the exemplary embodiment, when the first gas is supplied to the chamber, the temperature in the chamber may be maintained at the set temperature.

According to the exemplary embodiment, after the first gas and the second gas are supplied into the chamber, dissociation gas different from the first gas and the second gas may be supplied to the chamber, and the dissociation gas may be excited to remove the reactant and the protective film from the substrate.

According to the exemplary embodiment, the method may be performed in one cycle of supplying the dissociation gas after supplying the first gas and the second gas, the cycle being repeated multiple times.

According to the exemplary embodiment, dissociation gas different from the first gas and the second gas may be supplied to the chamber, prior to supplying the first gas and the second gas to the chamber.

According to the exemplary embodiment, the first gas may include CF₄, SF₆, Cl₂, or HBr, the second gas includes O₂, and the dissociation gas includes inert gas.

According to the exemplary embodiment, the hard mask film may include an additive including tungsten and a carbon layer.

According to the exemplary embodiment, a method of processing a substrate including an insulating film in which a nitride film and an oxide film are alternately laminated, and a hard mask film laminated on a top side of the insulating film, the method comprising: a main stripping operation in which first gas including CF₄, SF₆, Cl₂, or HBr is excited in a chamber to react with a hard mask film formed on a substrate to produce a reactant, and second gas including O₂ is excited in the chamber to etch the hard mask film or react with a surface of the insulating film to produce a protective film; and an over stripping operation in which after the main stripping operation, dissociation gas including inert gas is supplied to the chamber while applying bias power to a chuck supporting a substrate in the chamber to remove the reactant and the protective film from the substrate, wherein the hard mask film may include an additive and a carbon layer added with tungsten.

According to the exemplary embodiment, the reactant may be volatilized at a set temperature in a range of 100 degrees Celsius to 150 degrees Celsius.

### Advantageous Effects

According to the exemplary embodiment of the present invention, it is possible to efficiently treat the substrate.

Further, according to the exemplary embodiment of the present invention, it is possible to efficiently remove the hard mask film formed on the substrate.

Further, according to the exemplary embodiment of the present invention, it is possible to efficiently remove a hard mask film to which a specific substance has been added, while minimizing damage to an insulating film formed on the substrate.

Further, according to the exemplary embodiment of the present invention, it is possible to treat a substrate to satisfy the characteristics of a high selectivity ratio by using a hard mask film with a specific substance, while facilitating the removal of the hard mask film with a specific substance from the substrate.

The effect of the present invention is not limited to the foregoing effects, and the not-mentioned effects will be clearly understood by those skilled in the art from the present specification and the accompanying drawings.

### DESCRIPTION OF DRAWINGS

FIG. 1 is a diagram schematically illustrating a substrate treating apparatus in which a substrate processing method according to an embodiment of the present invention is performed.

FIG. 2 is a diagram schematically illustrating the appearance of a substrate being treated by a substrate processing method according to an embodiment of the present invention.

FIG. 3 is a flow chart of a substrate processing method according to an embodiment of the present invention.

FIG. 4 is a diagram schematically illustrating the appearance of a substrate being treated in a main stripping operation according to the embodiment of FIG. 3.

FIG. 5 is an enlarged view of portion A of FIG. 4.

FIG. 6 is a table illustrating the properties of the reactants produced in the main stripping operation according to the embodiment of FIG. 3.

FIG. 7 is a diagram schematically illustrating the appearance of a substrate being treated in an over stripping operation according to the embodiment of FIG. 3.

FIG. 8 is an enlarged view of portion B of FIG. 7.

FIG. 9 is a flow chart of a substrate processing method according to another embodiment of FIG. 3.

### BEST MODE

Hereinafter, an exemplary embodiment of the present invention will be described in more detail with reference to the accompanying drawings. An exemplary embodiment of the present invention may be modified in various forms, and the scope of the present invention should not be construed as being limited by the exemplary embodiment described below. The present exemplary embodiment is provided to more completely explain the present invention to those skilled in the art. Therefore, the shapes of components in the drawings are exaggerated to emphasize a clearer description.

Terms, such as first and second, are used for describing various constituent elements, but the constituent elements are not limited by the terms. The terms are used only to discriminate one constituent element from another constituent element. For example, without departing from the scope of the invention, a first constituent element may be named as a second constituent element, and similarly a second constituent element may be named as a first constituent element.

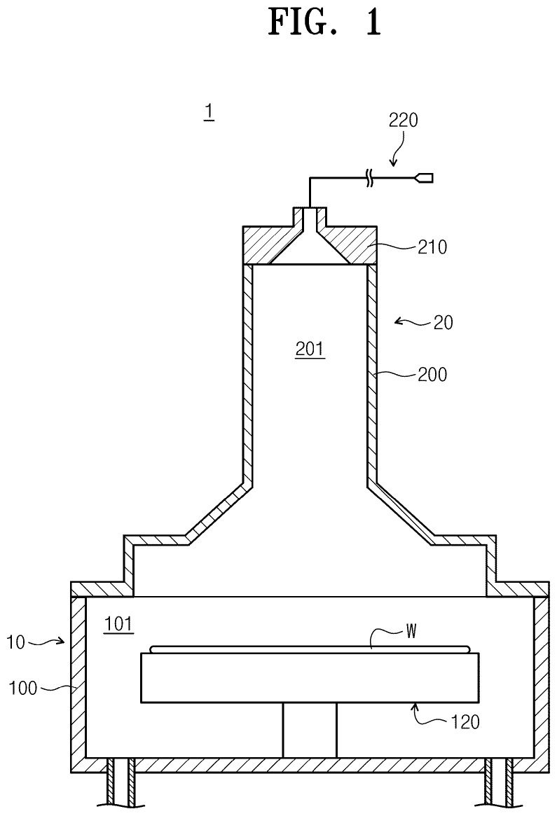

FIG. 1 is a diagram schematically illustrating a substrate treating apparatus in which a substrate processing method according to an exemplary embodiment of the present invention is performed.

Referring to FIG. 1, a substrate processing method according to an exemplary embodiment of the present invention may be performed in a substrate treating apparatus 1.

The substrate treating apparatus 1 according to the exemplary embodiment may perform a predetermined process on a substrate W by using plasma. The substrate W processed by the substrate treating apparatus 1 according to the exemplary embodiment may be in a state in which the photoresist film has been removed.

The substrate treating apparatus 1 according to the exemplary embodiment may strip a thin film on the substrate W. The thin film may be a film of various types, such as an oxide film, a nitride film, a silicon oxide film, a silicon nitride film, a polysilicon film, and a hard mask film. Optionally, the thin film may be a natural oxide film or a chemically generated oxide film. For example, the substrate treating apparatus 1 may strip a hard mask film formed on the substrate W. A detailed description of the substrate W treated in the substrate treating apparatus 1 will be described later.

The substrate treating apparatus 1 may include a treating unit 10 and a plasma generating unit 20. In the treating unit 10, the substrate W is treated. Further, in the plasma generating unit 20, plasma is generated.

The treating unit 10 may include a housing 100 and a chuck 120. The housing 100 has a treatment space 101. The treatment space 101 functions as a space for treating the substrate W. The treatment space 101 may include a substrate W. The housing 100 may be connected to a plasma chamber 200, which will be described later. An upper portion of the housing 110 may be open. Thus, the treatment space 101 is connected to a plasma generation space 201 described later. Furthermore, the housing 100 may be connected to an exhaust unit which is not illustrated. The atmosphere within the treatment space 101 may be exhausted to the outside of the treatment space 101 by the exhaust unit (not illustrated).

The chuck 120 is located within the treatment space 101. The chuck 120 supports the substrate W. The chuck 120 may be an ESC that supports the substrate W using electrostatic force. A heater which is not illustrated may be disposed inside the chuck 120. The heater (not illustrated) may heat the chuck 120. The heater (not illustrated) may heat the chuck 120 and raise the temperature of the substrate W supported on the chuck 120. Additionally, the chuck 120 may receive a voltage application from a power application module which is not illustrated. In the exemplary embodiment, the chuck 120 may receive a bias voltage application from a power application module (not illustrated).

In the plasma generating unit 20, plasma is generated. The plasma generating unit 20 may include a plasma chamber 200, a gas supply unit 220, and a plasma source (not illustrated).

The plasma chamber 200 has an inner space. The inner space may function as the plasma generation space 201 where plasma is generated. The plasma chamber 200 may have a shape with an open top and bottom surface. The open bottom surface of the plasma chamber 200 is connected to the treatment space 101 described above. The open top surface of the plasma chamber 200 may be sealed by a gas supply port 210.

The gas supply unit 220 may be connected with the gas supply port 210. Accordingly, the gas supply unit 220 may supply gas to the plasma generation space 201. The gas supplied to the plasma generation space 201 may be excited by a plasma source (not illustrated), which will be described later.

In the exemplary embodiment, the gas supply unit 220 may supply process gas and dissociation gas. The process gas may include first gas and second gas.

In the exemplary embodiment, the first gas may be gas that chemically reacts with a specific film formed on the substrate W. For example, the specific film formed on the substrate W may be a hard mask film. In the exemplary embodiment, the first gas may include CF₄, SF₆, Cl₂, or HBr. That is, the first gas may include gas of the halogen family.

In the exemplary embodiment, the second gas may be gas for etching a specific film formed on the substrate W (e.g., a hard mask film). Further, the second gas may be gas that chemically reacts with the thin films formed on the substrate W. For example, the second gas may be gas that reacts with an insulating film formed on the substrate W. In the exemplary embodiment, the second gas may include O₂.

In the exemplary embodiment, the dissociation gas may be gas that physically reacts with thin films formed on the substrate W (e.g., hard mask film, oxide film, or nitride film). For example, the dissociation gas may physically react with a hard mask film formed on the substrate W. In addition, the dissociation gas may physically react with the reactants and protective films described below. In other words, the dissociation gas in the exemplary embodiment may be gas that breaks the bonds formed by the compounds. In the exemplary embodiment, the dissociation gas may include inert gas. For example, the dissociation gas may include hydrogen (H₂), deuterium, or tritium, argon (Ar), Xe, Xr, or the like.

The plasma source (not illustrated) generates plasma. In the exemplary embodiment, the plasma source (not illustrated) may be an Inductively Coupled Plasma (ICP) including an antenna. However, without limitation, the plasma source (not illustrated) may be a Capacitively Coupled Plasma (CCP), Microwave Plasma, or any other device capable of generating plasma.

The plasma source (not illustrated) may apply high frequency power to the plasma generation space 201. The high frequency power applied to the plasma generation space 201 generates an electronic field in the plasma generation space 201. The gas supplied to the plasma generation space 201 may be excited to a plasma state by obtaining the energy required for ionization from the electric field generated in the plasma generation space 201.

FIG. 2 is a diagram schematically illustrating the appearance of a substrate being treated by a substrate processing method according to the exemplary embodiment of the present invention.

Referring to FIG. 2, the substrate W according to the exemplary embodiment of the present invention may be a substrate W in which the preceding process has been completed. As described above, the substrate W according to the exemplary embodiment may be a substrate W from which a photoresist film has been removed. In the exemplary embodiment, the substrate W may have thin films formed in a multilayer structure. An insulating film 300, which is an interlayer insulating film, and a hard mask film 400 may be formed on the substrate W according to the exemplary embodiment. The insulating film 300 and the hard mask film 400 may be laminated sequentially on the substrate W according to the exemplary embodiment of the present invention.

In the exemplary embodiment, the insulating film 300 may include a silicon oxide film and a silicon nitride film. The insulating film 300 may be laminated to a top side of the substrate W. For example, the insulating film 300 may be alternately laminated with the silicon oxide film and the silicon nitride film in a direction from bottom to top. However, the insulating film 300 may further include, but is not limited to, natural oxide films, chemically generated oxide films, polysilicon films, and the like. In addition, a plurality of pores may be formed in the insulating film 300 to reduce the dielectric constant.

The hard mask film 400 may be located on top of the insulating film 300. The hard mask film 400 according to the exemplary embodiment may include additives and a carbon layer. In the exemplary embodiment, the hard mask film 400 may include tungsten (Wolfram) as an additive. Additionally, the hard mask film 400 may include boron as an additive. The hard mask film 400 according to the exemplary embodiment may be Boron doped silicon, Tungsten ACL, AIOC (Ceramic carbon), WBC, or the like.

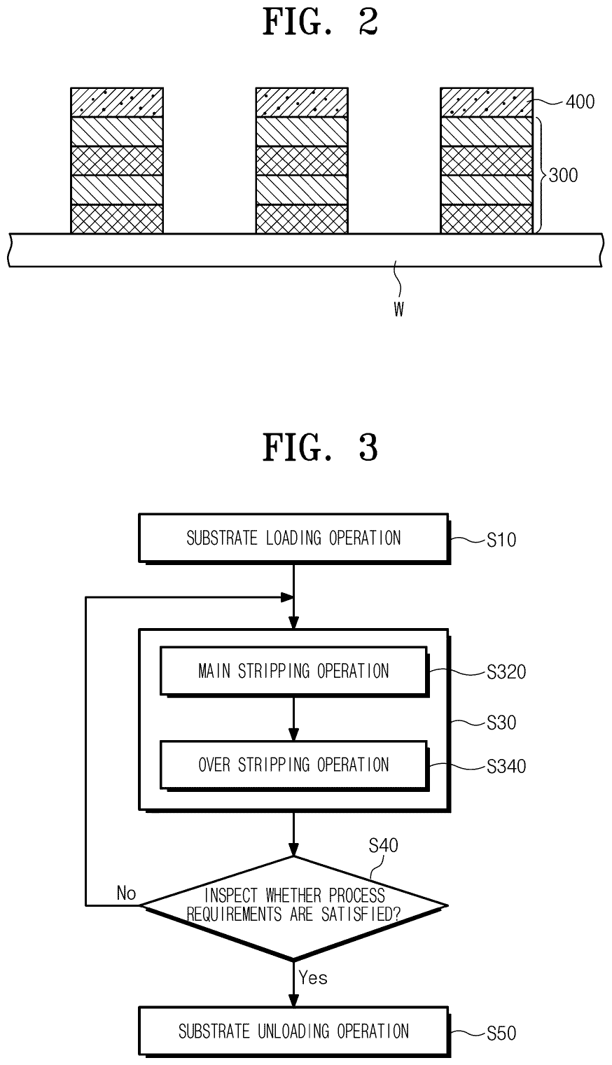

FIG. 3 is a flow chart of a substrate processing method according to an exemplary embodiment of the present invention.

The substrate processing method according to the exemplary embodiment described herein may be performed in the substrate treating apparatus 1 described with reference to FIG. 1. Accordingly, hereinafter, the drawing reference numerals referenced in FIGS. 1 and 2 will be cited as the same.

As illustrated in FIG. 3, the substrate processing method according to the exemplary embodiment of the present invention may include a substrate loading operation S10, a stripping operation S30, and a substrate unloading operation S50.

In the substrate loading operation S10, a substrate W is loaded into the substrate treating apparatus 1. Specifically, in the substrate loading operation S10, a transfer robot (not illustrated) loads the substrate W into the treatment space 101 and places the substrate W on the upper surface of the chuck 120.

In the stripping operation S30, a specific film formed on the substrate W may be stripped. That is, the stripping operation S30 may include removing the hard mask film 400 formed on the substrate W. The stripping operation S30 may include a main stripping operation S320 and an over stripping operation S340. The main stripping operation S320 may be referred to as a first stage for convenience, and the over stripping operation S340 may be referred to as a second stage.

The main stripping operation S320 and the over stripping operation S340 may be performed sequentially. That is, the substrate processing method according to the exemplary embodiment of the present invention may perform the over stripping operation S340 after performing the main stripping operation S320. The main stripping operation S320 and the over stripping operation S340 may be performed in one cycle. For example, the main stripping operation S320 and the over stripping operation S340 may be one cycle, and may be repeated sequentially. After the main stripping operation S320 is completed, the atmosphere of the treatment space 101 may be vented. Also, the atmosphere of the treatment space 101 may be vented after the over stripping operation S340 is completed.

In the substrate processing method according to the exemplary embodiment of the present invention, after performing the stripping operation S30, an operation S40 of inspecting whether the treated substrate W satisfies the process requirements may be performed. For example, after the main stripping operation S320 and the over stripping operation S340 are performed sequentially to complete a work cycle, the thickness of the hard mask film formed on the substrate W may be inspected. When the thickness of the inspected hard mask film does not conform to the process requirements, the stripping operation S30 is performed again. On the other hand, when the thickness of the inspected hard mask film conforms to the process requirements, the substrate unloading operation S50 described later is performed. That is, when the inspected hard mask film is completely removed from the substrate W, the stripping operation S30 is terminated and the substrate unloading operation S50 is performed. A detailed description of the main stripping operation S320 and the over stripping operation S340 will be described later.

The substrate unloading operation S50 includes unloading the substrate W from the treatment space 101. Specifically, in the substrate unloading operation S50, the transfer robot (not illustrated) receives the substrate W from the chuck 120 and unloads the substrate W to the outside of the treatment space 101. A subsequent process may be performed on the substrate W unloaded from the substrate treating apparatus 1.

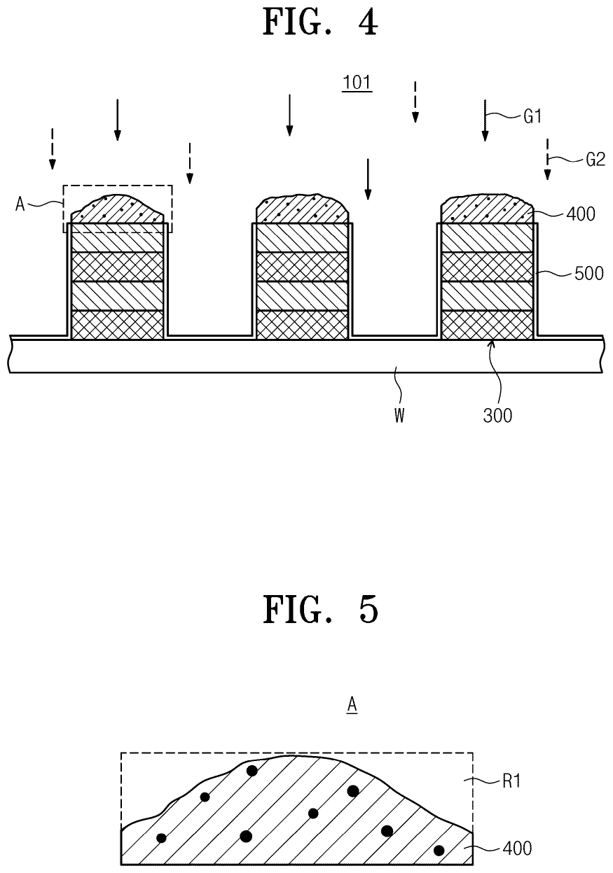

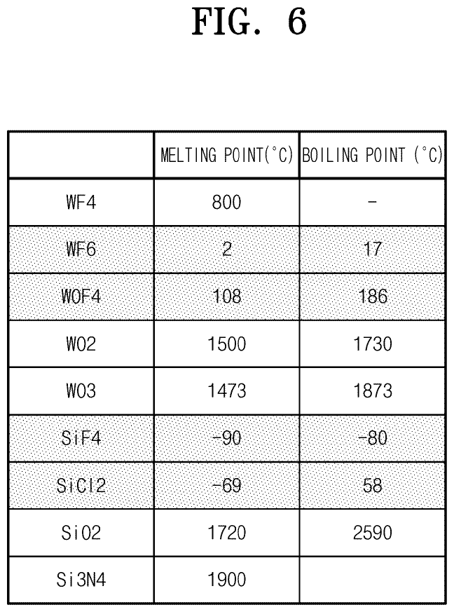

FIG. 4 is a diagram schematically illustrating the appearance of a substrate being treated in the main stripping operation according to the exemplary embodiment of FIG. 3. FIG. 5 is an enlarged view of portion A of FIG. 4. FIG. 6 is a table illustrating the properties of the reactants produced in the main stripping operation according to the exemplary embodiment of FIG. 3.

In the main stripping operation S320, process gas is supplied. According to the exemplary embodiment, the main stripping operation S320 may excite the first gas G1 and the second gas G2 to a plasma state and supply them to the treatment space 101.

While performing the main stripping operation S320, the temperature of the chuck 120 may be maintained at a set temperature. In the exemplary embodiment, a heater (not illustrated) disposed inside the chuck 120 may be heated to maintain the temperature of the chuck 120 within a range of 100 degrees Celsius to 150 degrees Celsius. More preferably, the temperature of the chuck 120 can be maintained within a range of 100 degrees Celsius to 130 degrees Celsius. The set temperature according to the exemplary embodiment may be a temperature at which the reactants can be readily volatilized, as described below. A detailed description of this will be given later.

During performing the main stripping operation S320, in addition to maintaining the temperature of the chuck 120 at the set temperature, the temperature of the treatment space 101 may be maintained at the set temperature. For example, during performing the main stripping operation S320, the temperature of the treatment space 101 may be maintained within a range of 100 degrees Celsius to 150 degrees Celsius. More preferably, the temperature of the treatment space 101 may be maintained within a range of 100 degrees Celsius to 130 degrees Celsius.

According to the exemplary embodiment, the main stripping operation S320 may supply the excited first gas G1 to the treatment space 101. As described above, the first gas G1 may include CF₄, SF₆, Cl₂, or HBr. That is, the first gas may include gas of the halogen family.

The first gas G1 supplied to the treatment space 101 may react with a specific film formed on the substrate W. For example, the first gas G1 may chemically react with the hard mask film 400 formed on the substrate W. The first gas G1 and the hard mask film 400 may react with each other to produce a reactant. For example, the first gas G1 may react with an additive (e.g., tungsten) added to the hard mask film 400. For example, when CF₄ gas is supplied to the treatment space 101, the CF₄ gas may react with the tungsten added to the hard mask film 400. As a result, a reactant such as WF₆ may be produced.

As illustrated in FIG. 6, the boiling point of the generated reactant, WF₆, is 17 degrees Celsius. Furthermore, in the main stripping operation S320 according to the exemplary embodiment of the present invention, the temperature of the treatment space 101 or the temperature of the chuck 120 is maintained in the range of 100 degrees Celsius to 150 degrees Celsius, so that the reactant may be volatilized and easily removed from the substrate W after being generated. Thus, the additives added to the hard mask film 400 may be easily removed from the substrate W.

According to the exemplary embodiment, the main stripping operation S320 may supply the second gas G2 excited to a plasma state to the treatment space 101. In the exemplary embodiment, the second gas G2 may include O₂. According to the exemplary embodiment, the first gas G1 and the second gas G2 supplied in the main stripping operation S320 may be supplied to the treatment space 101 simultaneously.

The second gas G2 supplied to the treatment space 101 may etch certain films formed on the substrate W. According to the exemplary embodiment, a portion of the second gas G2 supplied to the treatment space 101 may etch the hard mask film 400 formed on the substrate W. The hard mask film 400 may be etched while performing the main stripping operation S320. For example, as illustrated in FIG. 5, portion R1 of the hard mask film 400 may be etched while performing the main stripping operation S320. Specifically, a portion of the hard mask film 400 formed on the substrate W may be volatilized and removed from the substrate W after reacting with the first gas G1 to generate reactants, and another portion of the hard mask film 400 formed on the substrate W may be etched by the excited second gas G2 and removed from the substrate W.

In addition, other portions of the second gas G2 supplied to the treatment space 101 in the main stripping operation S320 may react with the thin films formed on the substrate W. According to the exemplary embodiment, the other portion of the second gas G2 may chemically react with the surface of the thin films formed on the substrate W. For example, another portion of the second gas G2 may react with the surface of the insulating film 300 formed on the substrate W to create a protective film 500. For example, O₂ gas, which is one example of the second gas G2, and Si present on the surface of the insulating film 300 may react to produce SiO₂, which is the protective film 500.

As described above, when performing the main stripping operation S320, the first gas G1 and the second gas G2 may be supplied to the treatment space 101 at the same time. Accordingly, when CF₄ gas, which is an example of the first gas G1, is supplied to the treatment space 101, if the Si present on the surface of the thin films formed on the substrate W reacts with the CF₄ gas, SiF₄ or SiCl₂ as illustrated in FIG. 6 may be generated. These compounds have very low boiling points, as illustrated in FIG. 6, and therefore volatize easily.

When SiF₄ or SiCl₂ is generated on the surface of the insulating film 300, it may easily volatilize and cause damage to the insulating film 300. That is, the first gas G1 supplied to the treatment space 101 in the main stripping operation S320 contributes to facilitating the removal of the additives added to the hard mask film 400, but it may react with the surface of the insulating film 300 and cause damage to the insulating film 300. Accordingly, according to the exemplary embodiment, the second gas G2 may be supplied to the treatment space 101 to etch and strip the hard mask film 400 while simultaneously forming the protective film 500 on the surface of the insulating film 300 to minimize damage to the insulating film 300 by the first gas G1.

According to the exemplary embodiment of the present invention described above, the mechanism by which the first gas G1 and the hard mask film 400 chemically react with each other to generate a reactant, the mechanism by which the second gas G2 etches the hard mask film 400, and the mechanism by which the second gas G2 chemically reacts with the thin films formed on the substrate W to generate the protective film 500 on the surface of the thin films are performed simultaneously without a time interval.

For example, when the first gas G1 is not supplied to the treatment space 101 and only the second gas G2 is supplied to the treatment space 101 to etch the hard mask film 400, compounds with very high melting and boiling points (e.g., WO₂, WO₃, or SiO₂) may be generated, as illustrated in FIG. 6. In this case, the produced compounds are not easily removed in subsequent processes due to their high melting and boiling points.

Accordingly, according to the exemplary embodiment of the present invention described above, the first gas G1 may be used to generate a reactant (e.g., WF₆) that may easily volatilize and remove an additive added to the hard mask film 400, and the second gas G2 may be used to etch the hard mask film 400, and at the same time, the second gas G2 may be used to prevent the insulating film 300 and the hard mask film 400 from being excessively etched by the first gas G1.

In the exemplary embodiment described above, the second gas G2 reacts with the surface of the insulating film 300 to generate a protective film 500 on the surface of the insulating film 300 by way of example, but the present invention is not limited thereto. For example, the second gas G2 may react with a surface of the hard mask film 400 to create a protective film on the surface of the hard mask film 400. The protective film generated on the surface of the hard mask film 400 may prevent the hard mask film 400 from being over-etched by the first gas G1 and/or the second gas G2.

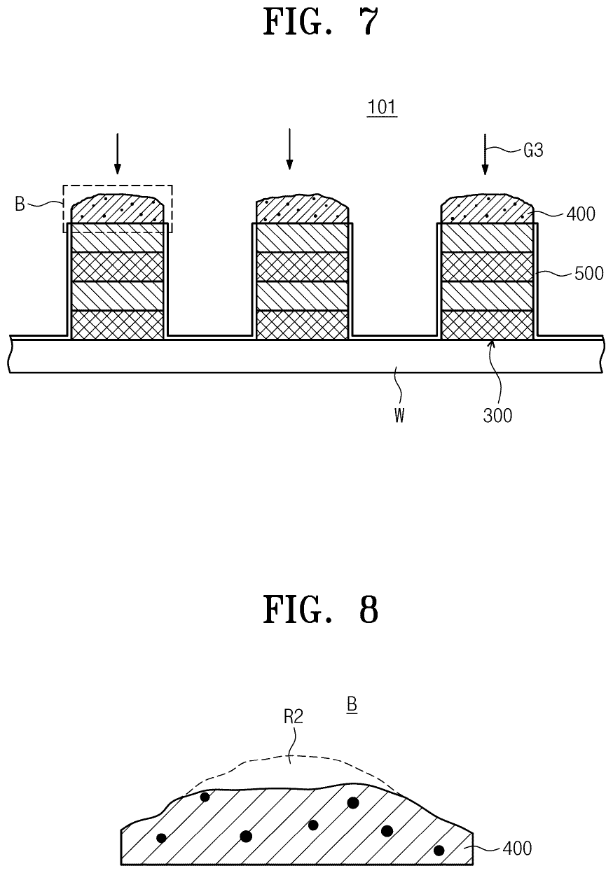

FIG. 7 is a diagram schematically illustrating the appearance of a substrate being treated in the over stripping operation according to the exemplary embodiment of FIG. 3. FIG. 8 is an enlarged view of portion B of FIG. 7.

In the over stripping operation S340 according to the exemplary embodiment of the present invention, dissociation gas G3 is supplied. In the exemplary embodiment, the over stripping operation S340 may include supplying dissociation gas G3 excited to a plasma state to the treatment space 101.

As described above, the dissociation gas G3 may be gas that physically reacts with the thin films formed on the substrate W. In the exemplary embodiment, the dissociation gas may be gas that breaks the bonds formed by the compounds. In the exemplary embodiment, the dissociation gas may include inert gas. For example, the dissociation gas may include hydrogen (H2), deuterium, or tritium, argon (Ar), Xe, Xr, or the like.

The dissociation gas can physically react with the hard mask film 400 formed on the substrate W. Furthermore, the dissociation gas G3 may physically react with reactants that have not been volatilized from the reactants generated in the main stripping operation S320. Thus, in the over stripping operation S340, the reactants that are not volatilized and removed in the main stripping operation S320 may be physically removed. For example, as illustrated in FIG. 8, portion R2 of the hard mask film 400 may be further etched by physical interaction with the dissociation gas G3 during the over stripping operation S340.

In addition, the dissociation gas G3 may weaken the bond between the carbon layer and the additives included in the hard mask film 400 on the substrate W. Furthermore, the dissociation gas G3 may physically react with the protective film 500 created on the surface of the thin films in the main stripping operation S320.

In the over stripping operation S340, a bias voltage may be applied to the chuck 120 (see FIG. 1), according to the exemplary embodiment of the present invention. Accordingly, the straightness of the dissociation gas G3 supplied to the treatment space 101 in the over stripping operation S340 may be improved. That is, the entrainment of the dissociation gas G3 supplied to the treatment space 101 in the over stripping operation S340 to the substrate W may be improved. Accordingly, the physical reactivity between the dissociation gas G3 and the thin films formed on the substrate W (e.g., insulating film 300, hard mask film 400, protective film 500, or reactants) may be enhanced. Accordingly, the dissociation gas G3 may weaken the bonding force of the thin films formed on the substrate W to facilitate removal of the thin films.

The main stripping operation S320 and the over stripping operation S340 described above may each be performed for a short time to minimize damage to the insulating film 300 formed on the substrate W. Further, the main stripping operation S320 and the over stripping operation S340 may be performed for a short period of time to prevent excessive etching of the hard mask film 400 formed on the substrate W. That is, the main stripping operation S320 and the over stripping operation S340 may each be performed within a range of a few seconds, and one cycle of the main stripping operation S320 and the over stripping operation S340 may be performed repeatedly multiple times.

Therefore, by performing the over stripping operation S340 according to the exemplary embodiment of the present invention described above, the hard mask film 400 formed on the substrate W may be efficiently removed because the binding force between the compounds may be weakened and the reactants not removed in the main stripping operation S320 may be removed.

Furthermore, in the over stripping operation S340, the dissociation gas G3 may be used to weaken the bonding force of the thin films formed on the substrate W. Therefore, when the main stripping operation S320 is performed again after the over stripping operation S340 because the process requirements are not satisfied after the over stripping operation S340, the chemical reaction between the first gas G1 and/or the second gas G2 and the thin films formed on the substrate W in the main stripping operation S320 may occur more easily. In other words, the over stripping operation S340 may improve the process efficiency in the main stripping operation S320, while at the same time reliably removing thin films that were not removed in the main stripping operation S320.

In the exemplary embodiment described above, CF₄ is used as the first gas G1 and O₂ is used as the second gas G2 by way of example, but the present invention is not limited thereto. For example, the type of first gas G1 and second gas G2 may be varied depending on the type of additives included in the hard mask film 400.

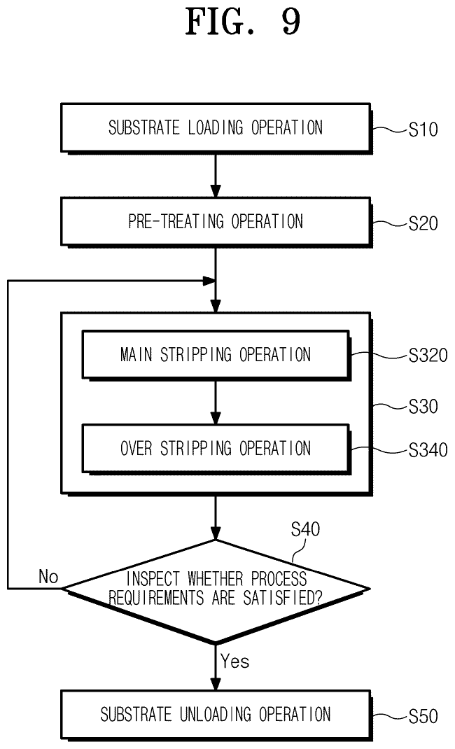

FIG. 9 is a flow chart of a substrate processing method according to another exemplary embodiment of FIG. 3.

The following describes a substrate processing method according to another exemplary embodiment of the present invention. Referring to FIG. 9, a substrate processing method according to the exemplary embodiment may include a substrate loading operation S10, a pre-treating operation S20, a stripping operation S30, and a substrate unloading operation S50.

Since the substrate loading operation $10, the stripping operation S30, and the substrate unloading operation S50 according to the exemplary embodiment are the same or similar to the substrate loading operation S10, the stripping operation S30, and the substrate unloading operation S50 according to the exemplary embodiment described with reference to FIGS. 3 to 8, a description of the overlap will be omitted hereinafter.

In the exemplary embodiment, the pre-treating operation S20 may be performed after the substrate loading operation S10. Further, the pre-treating operation S20 may be performed prior to performing the stripping operation S30.

The pre-treating operation S20 may provide dissociation gas to the treatment space. In the exemplary embodiment, the dissociation gas is the same as the dissociation gas supplied to the treatment space in the over stripping operation S340 described above. That is, the pre-treating operation S30 supplies dissociation gas to cause physical action on the thin films formed on the substrate W. For example, the dissociation gas may physically react with the hard mask film 400 formed on the substrate W.

Further, in the pre-treating operation S20, a bias voltage may be applied to the chuck 120. By applying a bias voltage to the chuck 120, the permeability of the dissociation gas to the substrate W may be improved. For example, the permeability of the hard mask film 400 among the thin films formed on the substrate W may be improved. That is, the binding force of the hard mask film 400 may be preemptively weakened in the pre-treating operation S20. Accordingly, the hard mask film 400 may be removed more efficiently in the subsequent stripping operation S30.

The foregoing detailed description illustrates the present invention. Further, the above content shows and describes the exemplary embodiment of the present invention, and the present invention may be used in various other combinations, modifications, and environments. That is, the foregoing content may be modified or corrected within the scope of the concept of the invention disclosed in the present specification, the scope equivalent to that of the invention, and/or the scope of the skill or knowledge in the art. The foregoing exemplary embodiment describes the best state for implementing the technical spirit of the present invention, and various changes required in the specific application field and use of the present invention are possible. Accordingly, the detailed description of the invention above is not intended to limit the invention to the disclosed exemplary embodiment. Further, the accompanying claims should be construed to include other exemplary embodiments as well.

1. A method of processing a substrate, the method comprising:
a first operation of supplying process gas to a chamber, wherein the process gas is excited to react with a specific film formed on a substrate to produce a reactant; and
a second operation of supplying dissociation gas to the chamber, wherein the dissociation gas is excited to remove the reactant from the substrate.

2. The method of claim 1, wherein the process gas includes first gas reacting with the specific film formed on the substrate, and
second gas that reacts with a surface of the film formed on the substrate to form a protective film on the surface or to etch the specific film.

3. The method of claim 2, wherein the dissociation gas further removes the protective film from the substrate.

4. The method of claim 3, wherein the first operation and the second operation are performed sequentially in one cycle, and repeated multiple times.

5. The method of claim 4, wherein the first gas includes CF₄, SF₆, Cl₂, or HBr,
the second gas includes O₂, and
the dissociation gas includes insert gas.

6. The method of claim 1, wherein the reactant is volatilized at a set temperature in a range of 100 degrees Celsius to 150 degrees Celsius.

7. The method of claim 6, wherein in the first operation, a chuck supporting the substrate within the chamber is maintained at the set temperature, and
in the second operation, bias power is applied to the chuck.

8. The method of claim 1, wherein the second operation is performed before the first operation.

9. The method of claim 1, wherein the specific film is a hard mask film.

10. The method of claim 9, wherein the hard mask film includes an additive including tungsten and a carbon layer.

11. A method of processing a substrate to remove a hard mask film formed on a substrate, the method comprising:
supplying first gas to a chamber, wherein the first gas is excited to react with a hard mask film formed on a substrate to produce a reactant, and
supplying second gas different from the first gas to the chamber, wherein the second gas is excited to etch the hard mask film or react with an insulating film formed on the substrate to produce a protective film on the surface of the insulating film, and
the first gas and the second gas are simultaneously supplied to the chamber.

12. The method of claim 11, wherein the reactant is volatilized at a set temperature in a range of 100 degrees Celsius to 150 degrees Celsius and removed from the substrate.

13. The method of claim 12, wherein when the first gas is supplied to the chamber, the temperature in the chamber is maintained at the set temperature.

14. The method of claim 11, wherein after the first gas and the second gas are supplied into the chamber, dissociation gas different from the first gas and the second gas is supplied to the chamber, and the dissociation gas is excited to remove the reactant and the protective film from the substrate.

15. The method of claim 14, wherein the method is performed in one cycle of supplying the dissociation gas after supplying the first gas and the second gas, the cycle being repeated multiple times.

16. The method of claim 11, wherein dissociation gas different from the first gas and the second gas is supplied to the chamber, prior to supplying the first gas and the second gas to the chamber.

17. The method of claim 14, wherein the first gas includes CF₄, SF₆, Cl₂, or HBr,
the second gas includes O₂, and
the dissociation gas includes insert gas.

18. The method of claim 11, wherein the hard mask film includes an additive including tungsten and a carbon layer.

19. A method of processing a substrate including an insulating film in which a nitride film and an oxide film are alternately laminated, and a hard mask film laminated on a top side of the insulating film, the method comprising:
a main stripping operation in which first gas including CF₄, SF₆, Cl₂, or HBr is excited in a chamber to react with a hard mask film formed on a substrate to produce a reactant, and second gas including O₂ is excited in the chamber to etch the hard mask film or react with a surface of the insulating film to produce a protective film; and
an over stripping operation in which after the main stripping operation, dissociation gas including inert gas is supplied to the chamber while applying bias power to a chuck supporting a substrate in the chamber to remove the reactant and the protective film from the substrate,
wherein the hard mask film includes an additive and a carbon layer added with tungsten.

20. The method of claim 19, wherein the reactant is volatilized at a set temperature in a range of 100 degrees Celsius to 150 degrees Celsius.
